(19) United States
(12) Patent Application Publication
(10) Pub. No.: US 2008/0073724 A1
(43) Pub. Date: Mar. 27, 2008

(54) DOUBLE LAYER ETCH STOP LAYER STRUCTURE FOR ADVANCED SEMICONDUCTOR PROCESSING TECHNOLOGY

(75) Inventors: Sheng-Hui Liang, Hsinchu (TW); Chia-Lin Chen, Jhubei City (TW); Chin-Yuan Ko, Hsinchu City (TW)

Correspondence Address: DUANE MORRIS LLP;IP DEPARTMENT (TSMC), 30 SOUTH 17TH STREET, PHILADELPHIA, PA, 19103-4196, US

(73) Assignee: TAIWAN SEMICONDUCTOR MANUFACTURING CO., LTD., Hsin-Chu (TW)

(21) Appl. No.: 11/534,536

(22) Filed: Sep. 22, 2006

(51) Int. Cl. H01L 29/94; H01L 21/8238

(52) U.S. Cl. 257/369; 438/199; 438/970

(57) ABSTRACT

A semiconductor device and a method for forming the same provides a double layer contact etch stop layer selectively formed over PMOS transistors with only a single silicon nitride contact etch stop layer formed over NMOS transistors on the same chip. The composite contact etch stop layer structure formed over the PMOS transistor avoids data retention and plasma induced damage issue associated with the PMOS transistor and a single silicon nitride contact etch stop layer formed over NMOS transistors avoids device shifting issues.

### FIELD OF THE INVENTION

The present invention relates, most generally, to semiconductor devices and methods for forming the same. More particularly, the present invention relates to an improved scheme for contact etch stop layers formed over NMOS and PMOS devices on the same substrate.

### BACKGROUND OF THE INVENTION

In today's rapidly advancing semiconductor manufacturing industry, etch stop layers are required even with superior etching selectivities, to prevent overetching into active devices such as PMOS or NMOS transistors when etching a relatively thick interlevel dielectric, ILD, formed over the active devices. The ILD is typically an oxide based layer and therefore the etch stop layer is advantageously formed of a material having a different etch rate than the ILD being etched or the underlying devices being exposed. When an opening is being formed through an ILD to create a contact to an underlying structure, the etch stop layer may be referred to as a contact etch stop layer, i.e., CESL.

The contact etch stop layers formed directly on active devices such as transistors have been found to have a profound influence on the quality, functionality and operational characteristics of the active device. Moreover, the various materials used as etch stop layers affect NMOS transistors and PMOS transistors differently. For example, Applicants have found that the change from an SiON film to an SiN film improves data retention in PMOS and NMOS devices. The use of the SiN film, however, creates substantial PID (plasma induced damage) failures, particularly in PMOS devices. In other words, there is a trade-off for PMOS devices between the use of a sole SiON layer which creates data retention issues but prevents PID failures, and the use of a sole SiN layer that creates PID failures but creates no data retention issues. Moreover, various films or combinations of films used as contact etch stop layers formed directly on transistor devices, can cause various other device shifts, i.e., shifts in the device's operational characteristics or parameters.

What is needed is a scheme of contact etch stop layers selectively formed over the various active devices that combine to form an integrated circuit device, such that the contact etch stop layers adequately serve their purpose without adversely affecting the underlying devices that the contact etch stop layer or layers are formed to protect.

### SUMMARY OF THE INVENTION

To address these and other objects and in view of its purposes, the present invention provides a method for forming a semiconductor device. The method comprises providing a substrate with at least an NMOS device and a PMOS device formed thereon and depositing a composite contact etch stop layer including an SiON layer and an SiN layer on the PMOS device and the SiN layer on the NMOS device. The SiN layer is formed to have a high tensile stress.

According to another aspect, the invention provides a semiconductor device. The device comprises a PMOS transistor and an NMOS transistor, each formed on a substrate. The PMOS transistor is covered by a composite contact etch stop layer including an SiON film and an SiN film and the NMOS transistor is covered by a single SiN film having a high tensile stress.

According to yet another aspect, the invention provides a semiconductor device comprising a PMOS transistor and an NMOS transistor, each formed on a substrate, and a composite contact etch stop layer disposed directly on the PMOS transistor. The composite contact etch stop layer includes an SiON film and an SiN film. The SiN film includes a high tensile stress and is also formed directly on the NMOS transistor. An interlevel dielectric film is formed directly on the composite contact etch stop layer over the PMOS transistor and directly on the SiN film over the NMOS transistor. A first opening extends through the interlevel dielectric, the SiON film and the SiN film thereby exposing the PMOS transistor, and a second opening extends through the interlevel dielectric and the SiN film, exposing the NMOS device.

### BRIEF DESCRIPTION OF THE DRAWING

The present invention is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIGS. 1A-1C are cross-sectional views illustrating a process sequence for forming inventive contact etch stop layers according to one exemplary embodiment of the invention;

FIGS. 2A-2C are cross-sectional views illustrating a process sequence for forming inventive contact etch stop layers according to another exemplary embodiment of the invention; and

FIGS. 3A-3C show an exemplary process sequence for forming contacts using the contact etch stop layers formed according to the invention.

### DETAILED DESCRIPTION

The present invention provides a semiconductor device such as an integrated circuit that includes both PMOS and NMOS devices and provides different, customized contact etch stop layer structures selectively formed over NMOS and PMOS devices. Applicants have found that in PMOS devices, there is a trade-off between an SiN contact etch stop layer which causes PID failures but causes no data retention issues and an SiON contact etch stop layer which causes data retention problems but prevents PID failures. Applicants have also found that a double layer contact etch stop layer, CESL, solves both data retention and PID issues for PMOS devices but causes a shift in operational characteristics of NMOS devices. Thus, for NMOS devices, there is a trade-off between a SiN, SiON double layer CESL structure that causes device shift and a single layer CESL which can create problems associated with having only a single film such as data retention and PID issues.

The present invention provides a selective CESL structure that solves both the problem of NMOS device shift and issues associated with PMOS devices such as data retention failures and plasma induced damage. The invention provides a composite etch stop layer including an SiN film and an SiON film formed over PMOS devices and a single SiN film formed over NMOS devices. The SiN film is formed to include a tensile stress. Further details are provided in conjunction with the process sequence details illustrated in the figures.

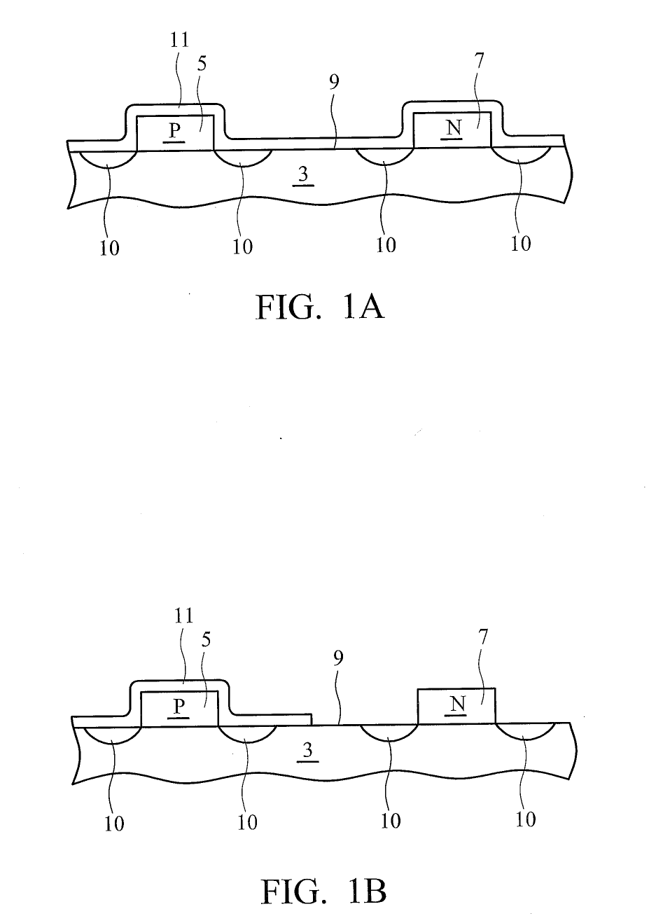

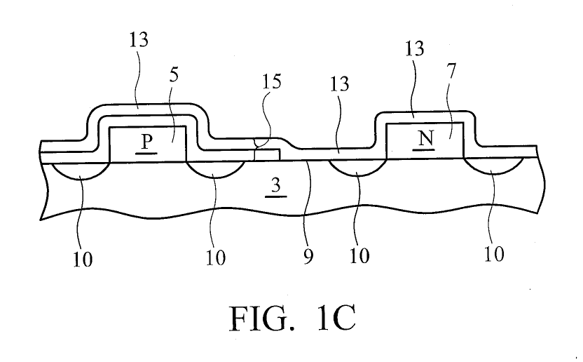

FIG. 1A shows a PMOS device and an NMOS device formed on a substrate. PMOS transistor 5 and NMOS transistor 7 are formed on substrate 3 which may be any conventional substrate used in semiconductor processing technology, such as a silicon substrate. In one advantageous embodiment, a plurality of PMOS transistors 5 and NMOS transistors 7 are formed within the same integrated circuit, i.e., on the same chip and each of the PMOS transistors 5 and NMOS transistors 7 is processed according to the following exemplary embodiments. PMOS transistor 5 and NMOS transistor 7 are formed on and in surface 9 of semiconductor substrate 3 using conventional methods. That is, the source/drain features 10 of the transistors, are formed in substrate 3 as is conventional. Various methods may be used to form SiON layer 11 over substrate 3 including over PMOS transistor 5 and NMOS transistor 7. SiON layer 11 may be a stoichiometric or non-stoichiometric silicon oxynitride film. In the illustrated embodiment, SiON layer 11 is formed directly on PMOS transistor 5 and NMOS transistor 7. SiON layer 11 may be formed using conventional methods. According to one exemplary embodiment, SiON layer 11 may include a thickness of 100 angstroms but other thicknesses ranging from 50-500 angstroms may be used in other exemplary embodiments. Conventional patterning techniques are then used to spatially selectively remove SiON layer 11 from over NMOS transistor 7 to produce the structure shown in FIG. 1 B which includes SiON layer 11 retained over PMOS transistor 5.

Silicon nitride, SiN layer 13 is then formed over the structure of FIG. 1 B to produce the structure shown in FIG. 1C. SiN layer 13 is a film that may include a thickness ranging from 200-300 angstroms in one exemplary embodiment, but other thicknesses may be used in other exemplary embodiments. Conventional techniques may be used to deposit SiN layer 13 directly on SiON layer 11 and directly on NMOS transistor 7 as in the illustrated embodiment. SiN layer 13 is a film that advantageously includes a high tensile stress such as a tensile stress greater than 0.5 GPa (Giga Pascals) and may advantageously be within the range of 0.5 to 2.0 GPa or 0.75 to 2.0 GPa. The structure of FIG. 1C therefore includes composite CESL 15 over PMOS transistor 5. Composite CESL 15 includes SiON layer 11 formed beneath SiN layer 13.

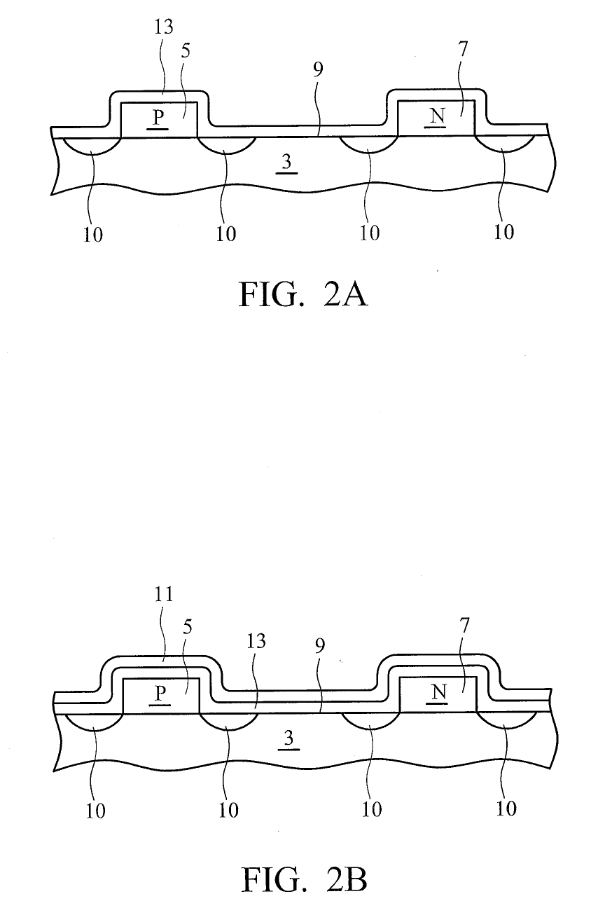

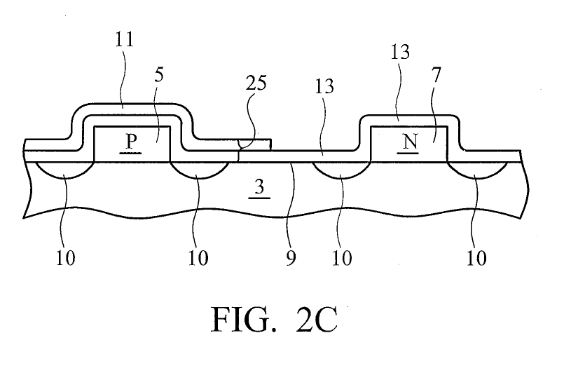

FIGS. 2A-2C illustrate another exemplary embodiment for forming a semiconductor device including a PMOS transistor and an NMOS transistor having different, selectively formed contact etch stop layers formed thereover. FIG. 2A shows substrate 3 having surface 9 and PMOS transistor 5 and NMOS transistor 7 formed over and in substrate 3. That is, the source/drain features 10 of the transistors, are formed in substrate 3 as is conventional. Like reference numbers denote like features previously described in the specification. SiN layer 13 is formed over PMOS transistor 5 and NMOS transistor 7 and in the illustrated embodiment, SiN layer 13 is formed directly on PMOS transistor 5 and NMOS transistor 7.

FIG. 2B shows SiON layer 11 formed directly on SiN layer 13 and over both PMOS transistor 5 and NMOS transistor 7. A conventional patterning sequence such as a photolithographic and etching process sequence is then used to selectively remove SiON layer 11 from over NMOS transistor 7, producing the structure shown in FIG. 2C which illustrates composite contact etch stop layer 25 formed over PMOS transistor 5 and a single SiN layer 13 formed over and directly on NMOS transistor 7. Composite etch stop layer 25 is formed directly on PMOS transistor 5 and includes SiON layer 11 disposed on SiN layer 13.

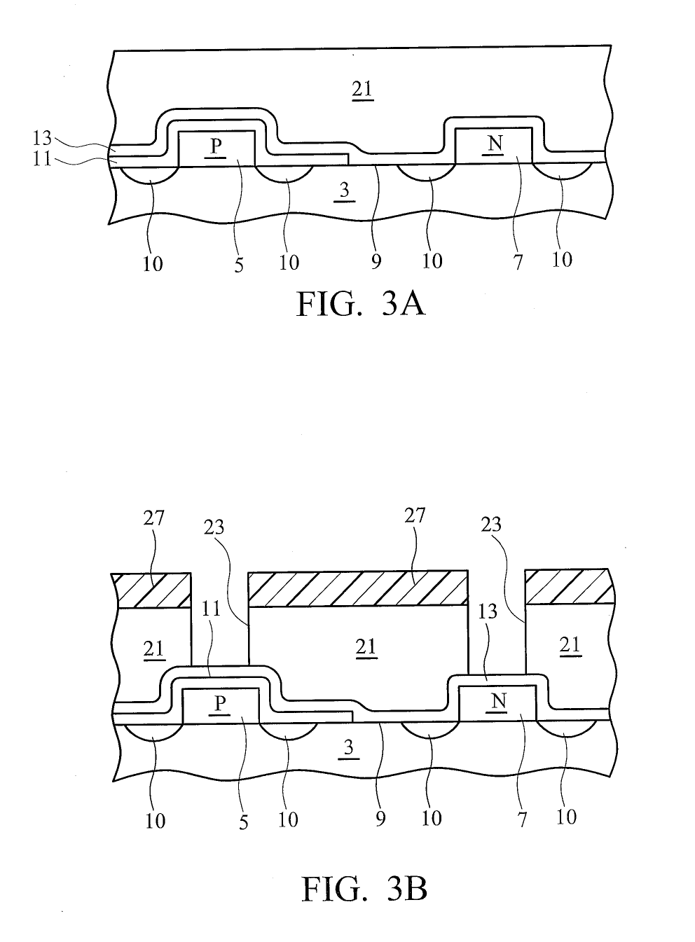

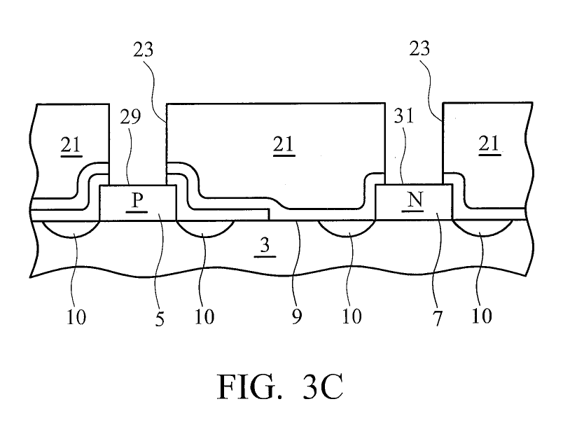

FIGS. 3A-3C illustrate a subsequent etching procedure utilizing the exemplary contact etch stop layer embodiment illustrated in FIG. 1C and represents the exemplary embodiment in which the composite contact etch stop layer formed over the PMOS transistor includes the nitride layer formed over the SiON layer although the opposite arrangement, such as illustrated in FIG. 2C, may equally be used. FIG. 1C shows substrate 3 having surface 9 and PMOS transistor 5 and NMOS transistor 7 formed over and in substrate 3. Composite contact etch stop layer 15 includes SiN layer 13 formed over SiON layer 11 and NMOS transistor 7 includes a single SiN layer 13 serving as an etch stop layer.

Now turning to FIG. 3A, interlevel dielectric, ILD 21 is formed over the structure shown in FIG. 1C, in particular ILD 21 is disposed directly on composite etch stop layer 15 over PMOS transistor 5 and directly on SiN layer 13 formed over NMOS transistor 7. Various ILD materials may be used to form ILD 21 which may be one or more layers and is generally an oxide-based material such as silicon dioxide, which may optionally be doped. Conventional techniques are used to form ILD 21.

Conventional patterning techniques are then used to form openings 23 within ILD 21. The conventional patterning techniques include the use of photoresist 27. The etching procedure initially etches through ILD 21 simultaneously forming openings 23 in the ILD 21, then exposing SiON layer 11 over PMOS transistor 5 and SiN layer 13 over NMOS transistor 7 as illustrated in FIG. 3B. SiON layer 11 and SiN layer 13 have different etch rates than the ILD 21 etch rate, in the etch process used to etch ILD 21.

The etching process continues advantageously using a different etch chemistry to remove composite contact etch stop layer 15 from over PMOS transistor 5 and SiN layer 13 from over NMOS transistor 7. Conventional etching techniques may be used. After these films are removed, and photoresist 27 is stripped, the structure shown in FIG. 3C results. One opening 23 exposes top surface 29 of PMOS transistor 5 and another opening 23 exposes top surface 31 of NMOS transistor 7. Contact is thereby provided to PMOS transistor 5 and NMOS transistor 7 without damaging the structures as a result of the contact etch stop layers utilized. Moreover, the contact etch stop layers do not engender any problems with the transistors they protect during the ILD etching process. For example, NMOS transistor 7 and PMOS transistor 5 are free of device shifting issues, data retention issues, and PID issues.

The techniques for selective formation of different contact etch stop layers over NMOS and PMOS transistors may be used in conjunction with various process flows used to form various semiconductor devices. For example, the process sequences may be used in 90 nm technology, 80 nm technology and may also be used for advanced technologies beyond 65nm technologies.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A semiconductor device comprising a PMOS transistor and an NMOS transistor, each formed on a substrate, said PMOS transistor covered by a composite contact etch stop layer including an SiON film and an SiN film, said NMOS transistor covered only by a single SiN film having a tensile stress.

2. The semiconductor device as in claim 1, wherein said composite contact etch stop layer includes said SiON film disposed directly on said SiN film.

3. The semiconductor device as in claim 1, wherein said composite contact etch stop layer includes said SiN film disposed directly on said SiON film.

4. The semiconductor device as in claim 1, wherein said tensile stress has a value in a range of about 0.5 to 2 GPa.

5. The semiconductor device as in claim 1, wherein said composite contact etch stop layer is disposed directly on said PMOS transistor and said SiN film is disposed directly on said NMOS transistor and further comprising an interlevel dielectric disposed directly on said composite etch stop layer and on said SiN film.

6. The semiconductor device as in claim 1, wherein said composite contact etch stop layer is disposed directly on said PMOS transistor and said SiN film is disposed directly on said NMOS transistor and further comprising:
an interlevel dielectric film formed directly on said composite contact etch stop layer over said PMOS transistor and directly on said SiN film over said NMOS transistor;
a first opening extending through said interlevel dielectric thereby exposing said composite contact etch stop layer over said PMOS transistor; and
a second opening extending through said interlevel dielectric and exposing said SiN film over said NMOS device.

7. A semiconductor device comprising
a PMOS transistor and an NMOS transistor, each formed on a substrate,
a contact etch stop layer including only an SiN film having a tensile stress formed directly on said NMOS transistor,
a composite contact etch stop layer disposed directly on said PMOS transistor, said composite contact etch stop layer including an SiON film and said SiN film,
an interlevel dielectric film formed directly on said composite contact etch stop layer over said PMOS transistor and directly on said SiN film over said NMOS transistor,
a first opening extending through said interlevel dielectric, said SiON film and said SiN film thereby exposing said PMOS transistor, and
a second opening extending through said interlevel dielectric and said SiN film and exposing said NMOS device.

8. The semiconductor device as in claim 7, wherein said composite contact etch stop layer comprises said SiON film disposed on said SiN film.

9. The semiconductor device as in claim 7, wherein said composite contact etch stop layer comprises said SiN film disposed on said SiON film.

10. The semiconductor device as in claim 7, wherein said tensile stress lies within a range of about 0.5 to 2 GPa.

11. The semiconductor device as in claim 7, wherein said semiconductor device comprises an integrated circuit.

12. A method for forming a semiconductor device, said method comprising:
providing a substrate with at least an NMOS device and a PMOS device formed thereon; and
depositing a composite contact etch stop layer including an SiON layer and an SiN layer on said PMOS device and only said SiN layer on said NMOS device, said SiN layer having a tensile stress greater than about 0.5 GPa.

13. The method as in claim 12, further comprising:
forming an interlevel dielectric (ILD) over each of said NMOS device and said PMOS device;
creating a first opening extending through said ILD and said composite contact etch stop layer thereby exposing said PMOS device; and
creating a second opening extending through said ILD and said SiN layer thereby exposing said NMOS device.

14. The method as in claim 13, wherein said creating a first opening and said creating a second opening includes initially etching said ILD using an etch process that etches said ILD at an etch rate being different than etch rates of said SiN layer and said SiON layer, thereby simultaneously forming ILD openings and exposing said composite etch stop layer over said PMOS device and exposing said SiN layer over said NMOS device.

15. The method as in claim 13, wherein said depositing comprises depositing said composite contact etch stop layer directly on said PMOS device and depositing said SiN layer directly on said NMOS device and wherein said forming an ILD comprises forming said ILD directly on said composite contact etch stop layer over said PMOS device and directly on said SiN layer over said NMOS device.

16. The method as in claim 15, wherein said creating a first opening and said creating a second opening includes initially etching said ILD using an etch process that etches said ILD at an etch rate being different than etch rates of said SiN layer and said SiON layer, thereby simultaneously forming ILD openings and exposing said composite etch stop layer over said PMOS device and exposing said SiN layer over said NMOS device.

17. The method as in claim 15, wherein each of said PMOS device and said NMOS device comprises a transistor.

18. The method as in claim 12, wherein said depositing comprises:
first forming said SiN layer over each of said PMOS device and said NMOS device;
then forming said SiON layer over each of said PMOS device and said NMOS device; and
then removing said SiON layer from over said NMOS device.

19. The method as in claim 12, wherein said depositing comprises;
first forming said SiON layer over said NMOS device and said PMOS device;
then removing said SiON layer from over said NMOS device, said SiON layer remaining over said PMOS device; and
then forming said SiN layer over said NMOS and PMOS devices.

20. The method as in claim 18, wherein said SiON layer is formed directly on each of said NMOS and PMOS devices and said SiN layer is formed directly on said SiON layer.
